(19) United States
(12) Patent Application Publication
(10) Pub. No.: US 2013/0186699 A1
(43) Pub. Date: Jul. 25, 2013

(54) HIGH VOLTAGE CONVERTERS FOR ELECTROSTATIC APPLICATIONS

(71) Applicants: Harsha E. PRAHLAD, Cupertino, CA (US); Ronald E. PELRINE, Longmont, CO (US); Philip A. VON GUGGENBERG, Redwood City, CA (US); Roy D. KORNBLUH, Palo Alto, CA (US); Joseph S. ECKERLE, Woodside, CA (US)

(72) Inventors: Harsha E. PRAHLAD, Cupertino, CA (US); Ronald E. PELRINE, Longmont, CO (US); Philip A. VON GUGGENBERG, Redwood City, CA (US); Roy D. KORNBLUH, Palo Alto, CA (US); Joseph S. ECKERLE, Woodside, CA (US)

(73) Assignee: SRI International, Menlo Park, CA (US)

(21) Appl. No.: 13/356,300

(22) Filed: Jan. 23, 2012

(51) Int. Cl. B60B 15/00; H01L 21/683; B60K 7/00

(52) U.S. Cl. 180/55; 361/234; 901/1

(57) ABSTRACT

A wall-crawling robot or other electroadhesive device can include a battery or other low voltage power source driving a motor that provides a primary device function, a voltage convertor adapted to convert the low voltage to a high voltage using the motor output, and electrodes configured to apply the high voltage to produce an electrostatic force between the electroadhesive device and a foreign substrate. The electrostatic force maintains a current position of the electroadhesive device relative to the foreign substrate, and the voltage convertor is separate from the primary function of the electroadhesive device. The primary function can be a mechanism for locomotion, and the voltage convertor can be a Van de Graff generator, a piezoelectric generator, or an inductive switch generator, any of which are driven in a secondary manner as a result of the motor output.

### TECHNICAL FIELD

The present invention relates generally to electroadhesion and other electrostatic applications, and more particularly to the use of high voltage converters for use in such applications.

### BACKGROUND

Successful controlled adhesion remains a desirable goal in many applications. Traditional controlled adhesion technologies, such as glues or other chemical adhesives, suction cups, and other vacuum based items, however, suffer from various drawbacks. Such drawbacks can include permanency, damage to or residue left at an applied surface, leaks, high power consumption (such as for vacuum pumps), and a limited effectiveness on wet, dusty or irregular surfaces, among others. Alternative adhesion techniques that attempt to avoid these various drawbacks should at least be sufficiently controllable, reliable, low power, and safe for consumer or commercial purposes.

The recent use of electroadhesive forces or electrostatic clamping as an alternative in controlled adhesion applications has proven to be advantageous on several levels. Such electroadhesive forces can be adapted to provide controlled adhesion on an electrically controllable basis without leaving residues or damaging surfaces. Electrostatic applications can also be fast acting in both on and off states, repeatable and strong, thus allowing repeatable modulation of material properties. Furthermore, a wider variety of dusty, slippery or irregular surfaces can be used with electroadhesive forces without detracting from a useful controlled adhesion outcome.

Unfortunately, significantly high voltages and electrical fields are often required in order for a suitable level of electroadhesive or electrostatic forces to be generated. As such, electroadhesive robots and other electrostatic devices typically need a high voltage power supply and/or an electrical convertor that is adapted to convert low voltages (i.e., battery voltages) to the high voltages needed for such electrostatic applications. Many commercially available electrical convertors can be used for such applications, but these items tend to be expensive and thus cost-prohibitive for many uses, such as for toys and other small consumer items.

In addition, various safety issues can arise when electrostatic forces are a primary focus for a commercially available and competitively priced consumer product. Such issues can include short circuiting, exposed electrodes, and the ability or need to manipulate multiple electrodes by an untrained operator or user. Traditional materials used for electrical applications can make it difficult or unduly costly to overcome such issues, resulting in product designs that can be overly cumbersome or bulky, so as to account for an appropriate level of user safety.

Although various electrical convertors and other applicable materials for have generally worked well for some electroadhesive type applications, there is always a desire to provide alternative and improved convertors and other materials. In particular, what is desired are relatively inexpensive and safe electrical convertors and other electroadhesive systems components that provide sufficient voltage levels for meaningful electrostatic forces in commercial applications.

### SUMMARY

It is an advantage of the present invention to provide improved high voltage electrical convertors for use in electrostatic applications. This can be accomplished at least in part through the use of one or more generators or other voltage converting arrangements that are adapted to leverage one or more already existing components of an overall device. Such existing components can include a motor adapted to drive a separate primary function of the overall device, although such a motor is not always required.

In various embodiments of the present invention, an electroadhesive device can include a low voltage power source, a motor adapted to receive power from the low voltage power source and provide an output that drives a primary function of the electroadhesive device, a voltage convertor adapted to receive power from the low voltage power source and convert the low voltage to a high voltage using the output of the motor, and one or more electrodes configured to apply the high voltage from the voltage convertor as an electrostatic adhesion voltage that produces an electrostatic force between the electroadhesive device and a foreign substrate. The electrostatic force can be suitable to maintain a current position of the electroadhesive device relative to the foreign substrate. In addition, the function of the voltage convertor can be separate from the primary function of the electroadhesive device.

In various detailed embodiments, the primary function of the electroadhesive device can be a mechanism for locomotion, such as to provide movement of the overall electroadhesive device. In some particular embodiments, the electroadhesive device can be a wall-crawling robot, with the mechanism for locomotion involving the movement of wheels or treads on the robot. In various embodiments, the voltage convertor can be a Van de Graff generator, while in other embodiments the voltage convertor can be a piezoelectric generator. In still further embodiment, the voltage convertor can be an inductive switch generator. Such an inductive switch generator can be adapted to provide pulses of high voltage, and may include a switch that is toggled by the output of the motor. The inductive switch generator may also include a transistor adapted to help control the timing of the switch toggling.

In various further embodiments, a power circuit adapted to increase the voltage of a low voltage power source for use in an electrostatic application is provided. The power circuit can include a low voltage power source adapted to drive a separate motor, as well as a voltage convertor adapted to receive power from the low voltage power source and convert the low voltage to a high voltage using an output of the separate motor. As in the foregoing embodiments, the voltage convertor may not be the primary function of the separate motor. Additional components can include one or more electrodes configured to apply the high voltage from the voltage convertor as an electrostatic adhesion voltage that produces an electrostatic force between an electroadhesive device including the power circuit and a foreign substrate. Again, the electrostatic force can be suitable to maintain a current position of the electroadhesive device relative to the foreign substrate. The voltage converter can include a magnetic component and a switching component adapted to charge and discharge the magnetic component, and said magnetic component can be an inductor while said switching component can be a transistor. Alternatively, the voltage convertor can be a Van de Graff generator or a piezoelectric generator.

In still further embodiments, various methods of operating an electroadhesive device are provided. Such methods can include the use of an electrical convertor that results in the provision of a sufficiently high voltage for an electrostatic application. Process steps can include providing power from a low voltage power source at the electroadhesive device, running a motor at the electroadhesive device using the power from the low voltage power source, converting the low voltage to a high voltage using the output of the motor, and adhering the electroadhesive device to a separate foreign substrate using one or more electrodes at the electroadhesive device. The electrodes can be configured to apply the high voltage as an electrostatic adhesion voltage that produces an electrostatic force between the electroadhesive device and the foreign substrate. In addition, the motor can drive a primary function of the electroadhesive device, with the voltage converting being separate from such a primary function. In some embodiments, the primary function can be a mechanism for locomotion, such as to move the overall device itself. In various detailed embodiments, the converting can involve the use of an inductive switch generator, with further process steps including utilizing an inductor and switch arrangement coupled to the low voltage power source, and toggling the switch using the output of the motor.

Other apparatuses, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The included drawings are for illustrative purposes and serve only to provide examples of possible structures and arrangements for the disclosed inventive high voltage convertors for electrostatic applications and systems. These drawings in no way limit any changes in form and detail that may be made to the invention by one skilled in the art without departing from the spirit and scope of the invention.

FIG. 1A illustrates in side cross-sectional view an exemplary electroadhesive device.

FIG. 1B illustrates in side cross-sectional view the exemplary electroadhesive device of FIG. 1A adhered to a foreign object.

FIG. 1C illustrates in side cross-sectional close-up view an electric field formed in the foreign object of FIG. 1B as result of the voltage difference between electrodes in the adhered exemplary electroadhesive device.

FIG. 2A illustrates in side cross-sectional view an exemplary pair of electroadhesive gripping surfaces or devices having single electrodes thereon.

FIG. 2B illustrates in side cross-sectional view the exemplary pair of electroadhesive gripping surfaces or devices of FIG. 2A with voltage applied thereto.

FIG. 3A illustrates in top perspective view an exemplary electroadhesive gripping surface in the form of a sheet with electrodes patterned on top and bottom surfaces thereof.

FIG. 3B illustrates in top perspective view an alternative exemplary electroadhesive gripping surface in the form of a sheet with electrodes patterned on a single surface thereof.

FIG. 4A illustrates in top perspective view an exemplary tracked wall-crawling robot modified with electroadhesive devices.

FIG. 4B illustrates in top perspective view an exemplary alternative tracked wall-crawling robot modified with electroadhesive devices.

FIG. 4C illustrates in side elevation view the exemplary wall-crawling robot of FIG. 4B moving from a horizontal surface to a vertical wall and to another horizontal surface.

FIG. 4D illustrates in side perspective view another exemplary tracked wall-crawling robot modified with electroadhesive devices according to one embodiment of the present invention.

FIG. 5 illustrates in block diagram format an exemplary power arrangement in an electrostatic device using a direct current to direct current voltage converter drive.

FIG. 6A illustrates in side elevation view an exemplary Van de Graff generator according to one embodiment of the present invention.

FIG. 6B illustrates in block diagram format an exemplary Van de Graff generator based power supply and voltage converter arrangement according to one embodiment of the present invention.

FIG. 7A illustrates in side elevation view an exemplary tracked wall-crawling robot modified with a piezoelectric generator according to one embodiment of the present invention.

FIG. 7B illustrates in side elevation view an exemplary piezoelectric element from the robot of FIG. 7A at a first position according to one embodiment of the present invention.

FIG. 7C illustrates in side elevation view the exemplary piezoelectric element of FIG. 7B at a second position according to one embodiment of the present invention.

FIG. 7D illustrates in side elevation view the exemplary piezoelectric element of FIG. 7B at a third position according to one embodiment of the present invention.

FIG. 7E illustrates in block diagram format an exemplary piezoelectric generator based power supply and voltage converter arrangement according to one embodiment of the present invention.

FIG. 8A illustrates a circuit diagram of an exemplary inductive switch generator arrangement according to one embodiment of the present invention.

FIG. 8B illustrates in block diagram format an exemplary inductive switch generator based power supply and voltage converter arrangement according to one embodiment of the present invention.

FIG. 9A illustrates in side elevation view an exemplary belt and roller arrangement of an electroadhesive device with respect to a foreign substrate according to one embodiment of the present invention.

FIG. 9B illustrates in top plan view an exemplary alternative belt and roller arrangement of an electroadhesive device with respect to a foreign substrate according to one embodiment of the present invention.

FIG. 10A illustrates a circuit diagram of an exemplary polarity reversal tank circuit for use in releasing an electrostatic clamp according to one embodiment of the present invention.

FIG. 10B provides a graph of an exemplary voltage output for the polarity reversal tank circuit of FIG. 10A according to one embodiment of the present invention.

FIG. 11A illustrates a circuit diagram of an exemplary alternative polarity reversal tank circuit having a damped sine wave according to one embodiment of the present invention.

FIG. 11B provides a graph of an exemplary voltage output for the alternative polarity reversal tank circuit having a damped sine wave of FIG. 11A according to one embodiment of the present invention.

FIG. 12 provides a flowchart of an exemplary method of operating an electroadhesive device according to one embodiment of the present invention.

### DETAILED DESCRIPTION

Exemplary applications of apparatuses and methods according to the present invention are described in this section. These examples are being provided solely to add context and aid in the understanding of the invention. It will thus be apparent to one skilled in the art that the present invention may be practiced without some or all of these specific details. In other instances, well known process steps have not been described in detail in order to avoid unnecessarily obscuring the present invention. Other applications are possible, such that the following examples should not be taken as limiting.

In the following detailed description, references are made to the accompanying drawings, which form a part of the description and in which are shown, by way of illustration, specific embodiments of the present invention. Although these embodiments are described in sufficient detail to enable one skilled in the art to practice the invention, it is understood that these examples are not limiting; such that other embodiments may be used, and changes may be made without departing from the spirit and scope of the invention.

The present invention relates in various embodiments to systems and methods for converting low voltage to high voltage for use in electrostatic applications. In some embodiments, this can involve electroadhesive robots and other electrostatic devices that utilize an electrical convertor to convert voltage from a battery or other suitable low voltage source to the relatively high voltages that these applications need. Various ways of cheaply, effectively, and safely generating the low power and high voltage required for these devices are provided herein. In some cases, power can be generated leveraging existing items or structures, substantially using parts such as driving belts, electroadhesive clamps and the like that are already located on the relevant robot or device. In this manner, the use of electroadhesion can apply to cost-sensitive applications such as consumer toys. Other embodiments can involve a more general application of voltage conversion for use in any electrostatic application, such as in an electrolaminate embodiment or arrangement.

In some examples, an electroadhesive device or system can be adapted to use existing and/or readily available and inexpensive parts to convert a low voltage to a high voltage using a Van de Graff (“VDF”) type generator, a piezoelectric generator, or an inductive switch generator. While these examples focus on particular aspects of specific electroadhesive applications, it will be understood that the various inventive principles and embodiments disclosed herein can be applied to other electrostatic applications and arrangements as well. For example, an electrolaminate application involving one or more electrostatically charged sheets can utilize the same types of general voltage conversion components and systems. The following disclosure provides an initial discussion regarding electroadhesion, followed by a brief description of wall-crawling robots as an exemplary electrostatic application, and then various details regarding high voltage convertors involving these different types of generators. Of course, other suitable types of generators and voltage conversions may also be used, as will be readily appreciated.

### Electroadhesion

As the term is used herein, “electroadhesion” refers to the mechanical coupling of two objects using electrostatic forces. Electroadhesion as described herein uses electrical control of these electrostatic forces to permit temporary and detachable attachment between two objects. This electrostatic adhesion holds two surfaces of these objects together or increases the traction or friction between two surfaces due to electrostatic forces created by an applied electrical field. Although electrostatic clamping has traditionally been limited to holding two flat, smooth and generally conductive surfaces separated by a highly insulating material together, the present invention involves electroadhesion devices and techniques that do not limit the material properties, curvatures, size or surface roughness of the objects subject to electroadhesive forces and handling. Furthermore, while the various examples and discussions provided herein typically involve electrostatically adhering a robot or other device to a foreign substrate, it will also be understood that many other types of electrostatic applications may also generally be implicated for use with the disclosed invention. For example, two components of the same device may be electrostatically adhered to each other, such as in an electrolaminate or other type of arrangement.

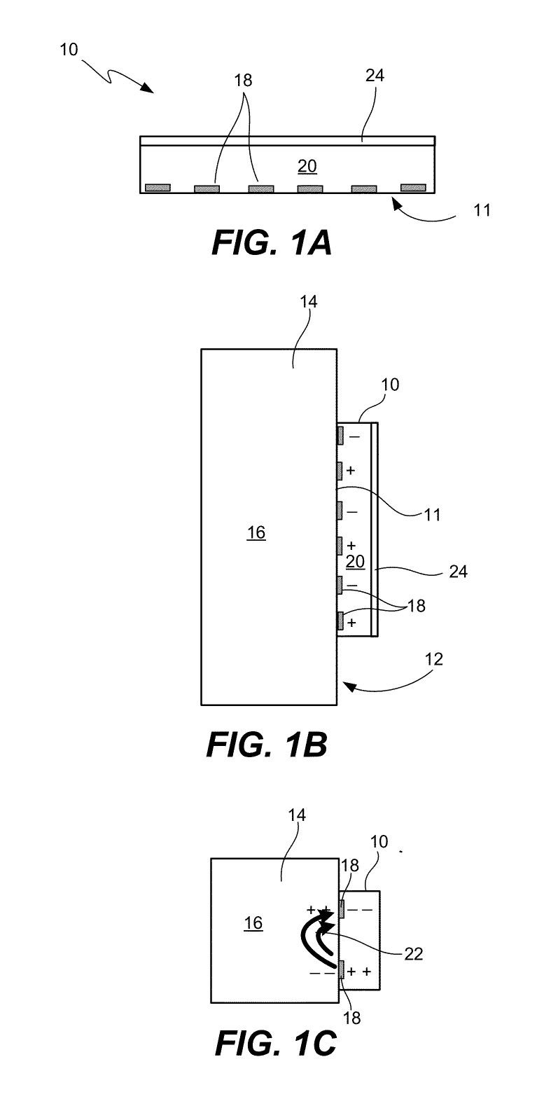

Turning first to FIG. 1A, an exemplary electroadhesive device according to one embodiment of the present invention is illustrated in elevated cross-sectional view. Electroadhesive device 10 includes one or more electrodes 18 located at or near an “electroadhesive gripping surface” 11 thereof, as well as an insulating material 20 between electrodes and a backing 24 or other supporting structural component. For purposes of illustration, electroadhesive device 10 is shown as having six electrodes in three pairs, although it will be readily appreciated that more or fewer electrodes can be used in a given electroadhesive device. Where only a single electrode is used in a given electroadhesive device, a complimentary electroadhesive device having at least one electrode of the opposite polarity is preferably used therewith. With respect to size, electroadhesive device 10 is substantially scale invariant. That is, electroadhesive device sizes may range from less than 1 square centimeter to greater than several meters in surface area. Even larger and smaller surface areas also possible, and may be sized to the needs of a given application.

FIG. 1B depicts in elevated cross-sectional view the exemplary electroadhesive device 10 of FIG. 1A adhered to a foreign object 14 according to one embodiment of the present invention. Foreign object 14 includes surface 12 and inner material 16. Electroadhesive gripping surface 11 of electroadhesive device 10 is placed against or nearby surface 12 of foreign object 14. An electrostatic adhesion voltage is then applied via electrodes 18 using external control electronics (not shown) in electrical communication with the electrodes 18. As shown in FIG. 1B, the electrostatic adhesion voltage uses alternating positive and negative charges on neighboring electrodes 18. As result of the voltage difference between electrodes 18, one or more electroadhesive forces are generated, which electroadhesive forces act to hold the electroadhesive device 10 and foreign object 14 against each other. Due to the nature of the forces being applied, it will be readily appreciated that actual contact between electroadhesive device 10 and foreign object 14 is not necessary. For example, a piece of paper, thin film, or other material or substrate may be placed between electroadhesive device 10 and foreign object 14. Furthermore, although the term “contact” is used herein to denote the interaction between an electroadhesive device and a foreign object, it will be understood that actual direct surface to surface contact is not always required, such that one or more thin objects such as an insulator, can be disposed between an electroadhesive gripping surface and the foreign object. In some embodiments such an insulator between the gripping surface and foreign object can be a part of the device, while in others it can be a separate item or device.

FIG. 1C illustrates in elevated cross-sectional close-up view an electric field formed in the foreign object of FIG. 1B as result of the voltage difference between electrodes in the adhered exemplary electroadhesive device 10. While the electroadhesive device 10 is placed against foreign object 14 and an electrostatic adhesion voltage is applied, an electric field 22 forms in the inner material 16 of the foreign object 14. The electric field 22 locally polarizes inner material 16 or induces direct charges on material 16 locally opposite to the charge on the electrodes 18 of the device, and thus causes electrostatic adhesion between the electrodes 18 (and overall device 10) and the induced charges on the foreign object 14. The induced charges may be the result of a dielectric polarization or from weakly conductive materials and electrostatic induction of charge. In the event that the inner material 16 is a strong conductor, such as copper for example, the induced charges may completely cancel the electric field 22. In this case the internal electric field 22 is zero, but the induced charges nonetheless still form and provide electrostatic force to the device 10. Again, an insulator may also be provided between the device 10 and foreign object 14 in instances where material 16 is copper or another strong conductor.

Thus, the electrostatic adhesion voltage provides an overall electrostatic force, between the electroadhesive device 10 and inner material 16 beneath surface 12 of foreign object 14, which electrostatic force maintains the current position of the electroadhesive device relative to the surface of the foreign object. The overall electrostatic force may be sufficient to overcome the gravitational pull on the foreign object 14, such that the electroadhesive device 10 may be used to hold the foreign object aloft. In various embodiments, a plurality of electroadhesive devices may be placed against foreign object 14, such that additional electrostatic forces against the object can be provided. The combination of electrostatic forces may be sufficient to lift, move, pick and place, or otherwise handle the foreign object. Electroadhesive device 10 may also be attached to other structures and hold these additional structures aloft, or it may be used on sloped or slippery surfaces to increase normal friction forces.

Removal of the electrostatic adhesion voltages from electrodes 18 ceases the electrostatic adhesion force between electroadhesive device 10 and the surface 12 of foreign object 14. Thus, when there is no electrostatic adhesion voltage between electrodes 18, electroadhesive device 10 can move more readily relative to surface 12. This condition allows the electroadhesive device 10 to move before and after an electrostatic adhesion voltage is applied. Well controlled electrical activation and de-activation enables fast adhesion and detachment, such as response times less than about 50 milliseconds, for example, while consuming relatively small amounts of power. Larger release times may also be valuable in many applications.

Electroadhesive device 10 includes electrodes 18 on an outside surface 11 of an insulating material 20. This embodiment is well suited for controlled attachment to insulating and weakly conductive inner materials 14 of various foreign objects 16. Other electroadhesive device 10 relationships between electrodes 18 and insulating materials 20 are also contemplated and suitable for use with a broader range of materials, including conductive materials. For example, a thin electrically insulating material (not shown) can be located on the surfaces of the electrodes where surface 12 is on a metallic object. As will be readily appreciated, a shorter distance between surfaces 11 and 12 results in a stronger electroadhesive force between the objects. Accordingly, a deformable surface 11 adapted to at least partially conform to the surface 12 of the foreign object 14 can be used.

As the term is used herein, an electrostatic adhesion voltage refers to a voltage that produces a suitable electrostatic force to couple electroadhesive device 10 to a foreign object 14. The minimum voltage needed for electroadhesive device 10 will vary with a number of factors, such as: the size of electroadhesive device 10, the material conductivity and spacing of electrodes 18, the insulating material 20, the foreign object material 16, the presence of any disturbances to electroadhesion such as dust, other particulates or moisture, the weight of any objects being supported by the electroadhesive force, compliance of the electroadhesive device, the dielectric and resistivity properties of the foreign object, and the relevant gaps between electrodes and foreign object surface. In one embodiment, the electrostatic adhesion voltage includes a differential voltage between the electrodes 18 that is between about 500 volts and about 15 kilovolts. Even lower voltages may be used in micro applications. In one embodiment, the differential voltage is between about 2 kilovolts and about 5 kilovolts. Voltage for one electrode can be zero. Alternating positive and negative charges may also be applied to adjacent electrodes 18. The voltage on a single electrode may be varied in time, and in particular may be alternated between positive and negative charge so as to not develop substantial long-term charging of the foreign object. The resultant clamping forces will vary with the specifics of a particular electroadhesive device 10, the material it adheres to, any particulate disturbances, surface roughness, and so forth. In general, electroadhesion as described herein provides a wide range of clamping pressures, generally defined as the attractive force applied by the electroadhesive device divided by the area thereof in contact with the foreign object.

The actual electroadhesion forces and pressure will vary with design and a number of factors. In one embodiment, electroadhesive device 10 provides electroadhesive attraction pressures between about 0.7 kPa (about 0.1 psi) and about 70 kPa (about 10 psi), although other amounts and ranges are certainly possible. The amount of force needed for a particular application may be readily achieved by varying the area of the contacting surfaces, varying the applied voltage, and/or varying the distance between the electrodes and foreign object surface, although other relevant factors may also be manipulated as desired.

Although electroadhesive device 10 having electroadhesive gripping surface 11 of FIG. 1A is shown as having six electrodes 18, it will be understood that a given electroadhesive device or gripping surface can have just a single electrode. Furthermore, it will be readily appreciated that a given electroadhesive device can have a plurality of different electroadhesive gripping surfaces, with each separate electroadhesive gripping surface having at least one electrode and being adapted to be placed against or in close proximity to the foreign object to be gripped. Although the terms electroadhesive device, electroadhesive gripping unit and electroadhesive gripping surface are all used herein to designate electroadhesive components of interest, it will be understood that these various terms can be used interchangeably in various contexts. In particular, while a given electroadhesive device might comprise numerous distinct “gripping surfaces,” these different gripping surfaces might themselves also be considered separate “devices” or alternatively “end effectors.”

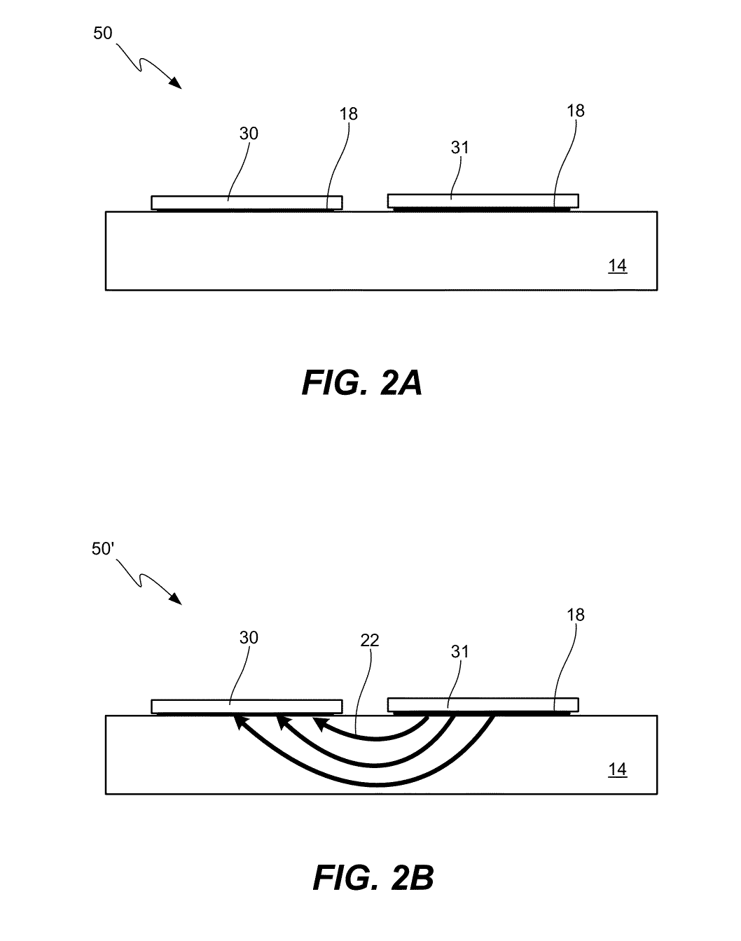

Referring to FIGS. 2A and 2B, an exemplary pair of electroadhesive devices or gripping surfaces having single electrodes thereon is shown in side cross-sectional view. FIG. 2A depicts electroadhesive gripping system 50 having electroadhesive devices or gripping surfaces 30, 31 that are in contact with the surface of a foreign object 16, while FIG. 2B depicts activated electroadhesive gripping system 50′ with the devices or gripping surfaces having voltage applied thereto. Electroadhesive gripping system 50 includes two electroadhesive devices or gripping surfaces 30, 31 that directly contact the foreign object 14. Each electroadhesive device or gripping surface 30, 31 has a single electrode 18 coupled thereto. In such cases, the electroadhesive gripping system can be designed to use the foreign object as an insulation material. When voltage is applied, an electric field 22 forms within foreign object 14, and an electrostatic force between the electroadhesive devices or gripping surfaces 30, 31 and the foreign object is created. Various embodiments that include numerous of these single electrode electroadhesive devices can be used, as will be readily appreciated.

In some embodiments, an electroadhesive gripping surface can take the form of a flat panel or sheet having a plurality of electrodes thereon. In other embodiments, the gripping surface can take a fixed shape that is matched to the geometry of the foreign object most commonly lifted or handled. For example, a curved geometry can be used to match the geometry of a cylindrical paint can or soda can. The electrodes may be enhanced by various means, such as by being patterned on an adhesive device surface to improve electroadhesive performance, or by making them using soft or flexible materials to increase compliance and thus conformance to irregular surfaces on foreign objects.

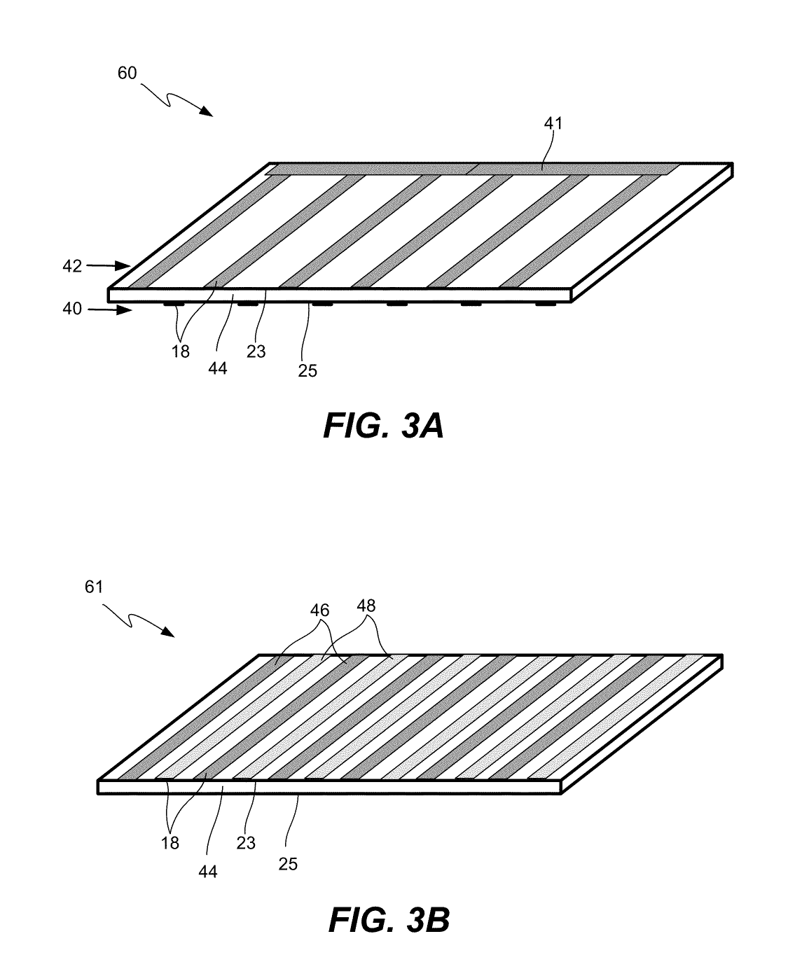

Continuing with FIGS. 3A and 3B, two examples of electroadhesive gripping surfaces in the form of flat panels or sheets with electrodes patterned on surfaces thereof are shown in top perspective view. FIG. 3A shows electroadhesive gripping surface 60 in the form of a sheet or flat panel with electrodes 18 patterned on top and bottom surfaces thereof. Top and bottom electrodes sets 40 and 42 are interdigitated on opposite sides of an insulating layer 44. In some cases, insulating layer 44 can be formed of a stiff or rigid material. In some cases, the electrodes as well as the insulating layer 44 may be compliant and composed of a polymer, such as an acrylic elastomer, to increase compliance. In one preferred embodiment the modulus of the polymer is below about 10 MPa and in another preferred embodiment it is more specifically below about 1 MPa. Various types of compliant electrodes suitable for use with the present invention are generally known, and examples are described in commonly owned U.S. Pat. No. 7,034,432, which is incorporated by reference herein in its entirety and for all purposes.

Electrode set 42 is disposed on a top surface 23 of insulating layer 44, and includes an array of linear patterned electrodes 18. A common electrode 41 electrically couples electrodes 18 in set 42 and permits electrical communication with all the electrodes 18 in set 42 using a single input lead to common electrode 41. Electrode set 40 is disposed on a bottom surface 25 of insulating layer 44, and includes a second array of linear patterned electrodes 18 that is laterally displaced from electrodes 18 on the top surface. Bottom electrode set 40 may also include a common electrode (not shown). Electrodes can be patterned on opposite sides of an insulating layer 44 to increase the ability of the electroadhesive end effector 60 to withstand higher voltage differences without being limited by breakdown in the air gap between the electrodes, as will be readily appreciated.

Alternatively, electrodes may also be patterned on the same surface of the insulating layer, such as that which is shown in FIG. 3B. As shown, electroadhesive gripping surface 61 comprises a sheet or flat panel with electrodes 18 patterned only on one surface thereof. Electroadhesive gripping surface 61 can be substantially similar to electroadhesive gripping surface 60 of FIG. 3A, except that electrodes sets 46 and 48 are interdigitated on the same surface 23 of a compliant insulating layer 44. No electrodes are located on the bottom surface 25 of insulating layer 44. This particular embodiment decreases the distance between the positive electrodes 18 in set 46 and negative electrodes 18 in set 48, and allows the placement of both sets of electrodes on the same surface of electroadhesive gripping surface 61. Functionally, this eliminates the spacing between the electrodes sets 46 and 48 due to insulating layer 44, as in embodiment 60. It also eliminates the gap between one set of electrodes (previously on bottom surface 25) and the foreign object surface when the top surface 23 adheres to the foreign object surface. Although either embodiment 60 or 61 can be used, these changes in the latter embodiment 61 do increase the electroadhesive forces between electroadhesive gripping surface 61 and the subject foreign object to be handled.

### Wall Crawling Robots

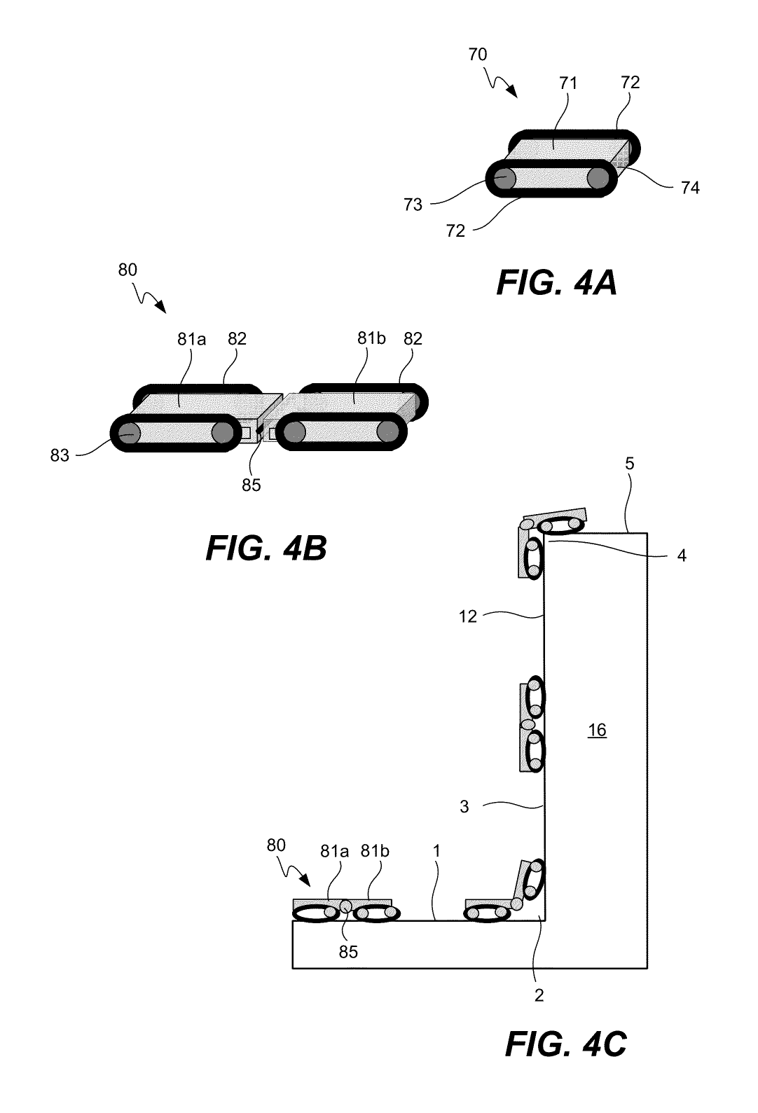

It will be readily appreciated that electrically controlled adhesion finds wide use in a wide variety of devices and applications. For example, various toys, tools or other devices designed or adapted for wall crawling or other forms of locomotion are well suited to use the electroadhesive devices and methods described herein. Turning next to FIG. 4A, an exemplary tracked wall-crawling robot modified with electroadhesive devices is illustrated. Robot 70 comprises a single electrostatic device or segment 71 that includes two tracks 72 situated around axled wheels or rollers 73 on left and right sides of a chassis 74. In some cases, a single continuous electroadhesive device may be employed that attaches to both left and right side of chassis 74 (similar to a conveyor belt).

Chassis 74 provides structural support between rollers or wheels 73, which interface with track or tracks 72. Chassis 74 can also include all portable locomotion requirements for robot 70, with such items (not shown) possibly including a battery or other power source, one or more motors to turn the rollers or wheels, wireless communication equipment and interfaces, payload such as a camera, and so forth.

Tracks 72 can include one or more compliant electroadhesive devices on their outer surface. In one embodiment, the electroadhesive devices continuously follow along the track length without interruption. Both the mechanical structure of tracks 71 and compliant electroadhesive devices disposed thereon can conform around rough or uneven surfaces. Tracks 72 offer a large electroadhesive surface area, without requiring an appreciable mass. In addition, the tracks offer a reliable, robust, and proven way for locomotion on unstructured and unpredictable terrain—both flat and vertical.

To turn, one or both tracks 72 slide relative to a surface. During turning, electroadhesion between one or both tracks 72 and the surface may be reduced. In addition, control of the electroadhesion pressures on individual tracks 72 can be used to steer the vehicle without any additional mechanisms, thereby providing a simple and lightweight steering mechanism. In other cases, the speed of track 72 may be changed on one side of the robot relative to the other.

FIG. 4B illustrates in top perspective view an exemplary alternative tracked wall-crawling robot modified with electroadhesive devices. Robot 80 includes multiple devices or segments 81a, 81b and a hinge 85 that permits pivoting between the segments. Segments 81a and 81b can be capable of pivoting relative to each other about hinge 85, while each is capable of independently maintaining adhesion to a wall surface via tracks 82 and wheels or rollers 83. This allows wall-crawling robot 80 to successfully negotiate the inner and outer corners of a building, for example. Although not shown, robot 80 may include more than two segments, such as three, four, ten, or more.

FIG. 4C illustrates in side elevation view the exemplary wall-crawling robot of FIG. 4B moving from a horizontal surface to a vertical wall and to another horizontal surface. As shown, robot 80 can be adapted to travel along floor 1, past inner corner 2, up vertical wall 3, over outer corner 4, and across roof 5. In so doing, the forward segment 81b can be adapted to pivot about hinge 85 with respect to the rear segment 81a. For example, with respect to traversing inner corner 2, forward segment 81b raises and folds upwards while rear segment 81a provides traction and electroadhesion until the forward segment clamps to the vertical surface 12 of wall 3. Although not shown, it will be readily appreciated that wall-crawling robot 80 may be capable of movement in both forward and reverse directions (e.g., by reversing the direction of wheels). In this case, segment 81a becomes the forward segment while segment 81b becomes the trailing segment.

For an outer corner 4 (where vertical wall 3 meets roof 5), the forward segment 81b first comes into contact with roof 5, which can be about orthogonal to vertical wall 3, and then drags the rest of the robot 80 with it. Once transition of one-half of robot 80 has been achieved, adhesion of trailing segment 81a can be switched off, temporarily making the robot 80 a front-wheel drive vehicle until the rear tracks gain adhesion to the surface of the roof 5. This results in the ability to easily transition across orthogonal surfaces and reduces power consumption.

In one specific embodiment, some of the rollers or wheels 83 are passive and do not provide rotational power. In another specific embodiment, some of the wheels 83 are spring loaded and can move slightly to maintain and increase the amount of contact with the wall as the robot turns upwards. Other arrangements are also possible, as will be readily appreciated.

FIG. 4D provides another example of a wall-crawling robot in side perspective view. Robot 90 is shown as being adhered to a vertical wall and in position to move up or down the wall, as may be desired. As shown, robot 90 includes a single device or segment 91 including a plurality of tracks 92 situated around wheels 93 that are positioned to both sides of a main chassis 94. A plurality of electrostatic components 96 in the form of thin foils rotate with the tracks 92 to alternatively come in contact with and disengage from wall surface 12.

Although a brief overview of wall-crawling robots has been provided, it will be readily appreciated that such devices represent only a small subset of the wide variety of devices and items that can be used in conjunction with electroadhesion and electrostatic applications. It will be understood that any and all such robots and other devices can be used in conjunction with the various high voltage converter systems and devices disclosed herein. Further, various additional details and embodiments regarding electroadhesion, electrolaminates, electroactive polymers, wall-crawling robots, and applications thereof can be found at, for example, commonly owned U.S. Pat. Nos. 6,586,859; 6,911,764; 6,376,971; 7,411,332; 7,551,419; 7,554,787; and 7,773,363; as well as International Patent Application No. PCT/US2011/029101; and also U.S. patent application Ser. No. 12/762,260, each of the foregoing of which is incorporated by reference herein in its entirety and for all purposes.

### High Voltage Converters

As noted above, one important factor in creating a useful level of electroadhesion is to have at least a localized region of high voltage. Such high voltage must either be provided directly from a high voltage power source, or must be formed by way of an electrical convertor from a low voltage power source, such as a battery. Since it is generally desirable to have mobile, portable and self-contained robots and other devices that make use of the various electrostatic principles outlined and referenced above, the use of common types of commercially available batteries would be ideal. As such, the ability to have relatively inexpensive and safe electrical convertors that provide sufficiently high voltage levels for meaningful electrostatic forces would be helpful.

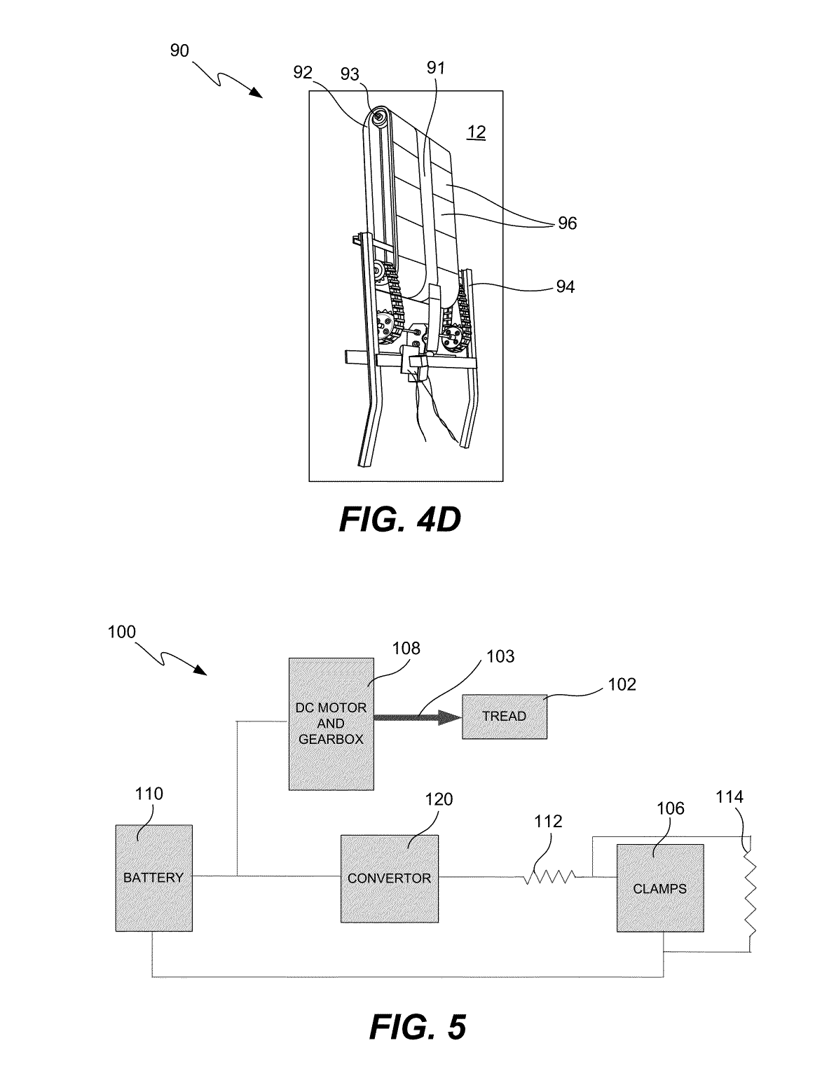

Moving first to FIG. 5, a power arrangement in an electrostatic device using a direct current (“DC”) to DC voltage converter drive is presented in block diagram format. Power arrangement 100 can include a low voltage power source, such as battery 110. In a particular non-limiting example provided for purposes of illustration only, the power source can be four serially arranged 1.5 volt “AA” sized batteries. The battery (or batteries) 110 can be adapted to provide power to a DC driven motor 108, which may include a gearbox arrangement and other mechanical components, as will be readily appreciated. Motor 108 can be adapted to drive a primary function of the overall device, such as wheels and/or treads 102.

In addition to providing power to the motor 108, the low voltage power source or battery 110 can also provide power to be used for electroadhesion or other electrostatic purposes. Such electroadhesion can be conducted by one or more electrostatic clamps 106, which can include electrodes, insulators and the like, as set forth in greater detail above. In order to ramp up the low voltage from the battery 110 to the high voltage needed for electrostatic applications, an electrical convertor 120 is provided between the battery and clamps 106. Such a convertor 120 can be a typical DC-DC voltage convertor or a boost circuit based equivalent, as will be readily appreciated. In some cases, one or more optional currently limiting series or parallel discharge resistances 112, 114 can also be provided. Such resistances can be built into the electroadhesive clamps, such as by using high resistance electrodes or encasing the electroadhesive pads in coatings with an appropriate leakage designed therein. Other ways of forming and arranging discharge resistances 112, 114 can also be used, as will be readily appreciated.

The use of traditional off-the-shelf DC-DC voltage convertor drives such as convertor 120, however, can be relatively expensive. Custom design and fabrication can reduce the price of these components somewhat, but this may not be adequate for some applications, and can result in more unknowns and complexity. As such, alternative high voltage convertors that are less expensive would be preferable.

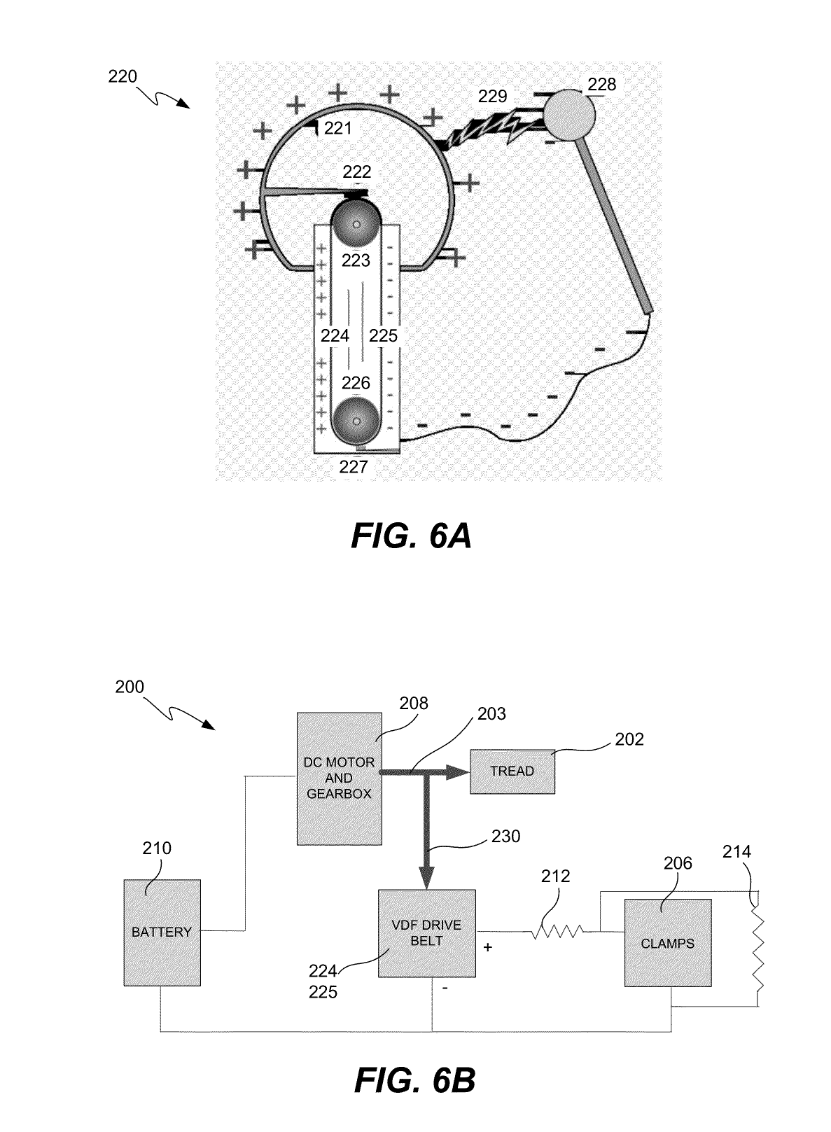

Turning next to FIG. 6A, an exemplary Van de Graff generator is shown in side elevation view. VDF generator 220 can include hollow metallic sphere 221 and an electrode 222 connected to the sphere. Electrode 222 can include a brush that ensures contact between the electrode and the drive belt 224, 225. An upper roller 223 and lower roller 226 can be adapted to drive the drive belt, which includes a positively charged side 224 and a negatively charged side 225. A lower electrode 227 can provide a ground for the system, and a spherical device 228 can be loaded with negative charges to facilitate discharging of the hollow metallic sphere 221. Such a discharge is represented by spark 229, which is produced by the difference in electrical potentials between hollow metallic sphere 221 and spherical device 228.

Such a VDF generator 220 is a generally well known way of producing a high voltage from the motion of mechanical parts. Use of such a mechanical approach for generating a high voltage can eliminate the need for a relatively expensive DC-DC convertor, and possibly even a battery in some cases. In various embodiments, the VDF generator can be used to power the electroadhesive robot or device. In lieu of a battery, a wind-up mechanism, spring or other mechanical component can be used to run the drive belt 224, 225 such that both the VDF generator becomes charged and the whole device is powered thereby. Alternatively, the drive belt can be driven using a separate motor that is powered by a battery or another low voltage source. In some embodiments, high voltages produced by the VDF generator can be stored in a capacitor for a more controlled discharge or use. For example, charge stored in a capacitor can be used to power the device when the motor, wind-up, spring or other source is not actively running.

FIG. 6B illustrates in block diagram format an exemplary Van de Graff generator based power supply and voltage converter arrangement. Power arrangement 200 can be similar to power arrangement 100 above in that it includes a low voltage power source, such as battery 210, that provides power to a DC driven motor 208, which may similarly include a gearbox arrangement and other mechanical components. Motor 208 can similarly be adapted to drive a primary function of the overall device, such as wheels and/or treads 202. Electroadhesion can similarly be conducted by one or more electrostatic clamps 206, which can include electrodes, insulators and the like. In addition, one or more optional currently limiting series or parallel discharge resistances 212, 214 can also be provided.

Unlike the foregoing arrangement, however, power arrangement 200 can include a VDF generator to facilitate ramping up the low voltage from the battery 210 to the high voltage needed for electrostatic applications. As such, the VDF drive belt 224, 225 in particular can be used as the electrical convertor to increase the voltage. Significantly, the VDF drive belt can be driven as an output of the motor 208, with such a relationship being shown at 230. While motor output 230 can be mechanical in nature, other types of outputs are also contemplated. While the primary function of the motor 208 can be considered as driving the tread 202 (or alternatively some other function in lieu of tread or wheel driving), the secondary function 230 of driving the VDF drive belt in order to convert low voltage to high voltage enables the use of existing components (e.g., motor 208) to leverage a less expensive voltage convertor.

In a particular application, power arrangement 200 utilizing a VDF generator 220 can be applied to an electroadhesive device, such as the wall-crawling robot 90 set forth above. In such an arrangement, the plurality of electrostatic components 96 can be analogous to the hollow metallic sphere 221 of a VDF generator, while one or more of the tracks 92 can similarly be analogous as the drive belt 224, 225 of a VDF generator. In some embodiments, the VDF drive belt can be the same belt that drives the wheels or treads of the robot 90. With at least some of the existing components being used as VDF generator parts, other components needed to complete a VDF type generator can be provided to complete the system. The resulting multifunctional uses of existing device parts can then result in more eloquent and less expensive driving circuits for electroadhesive applications.

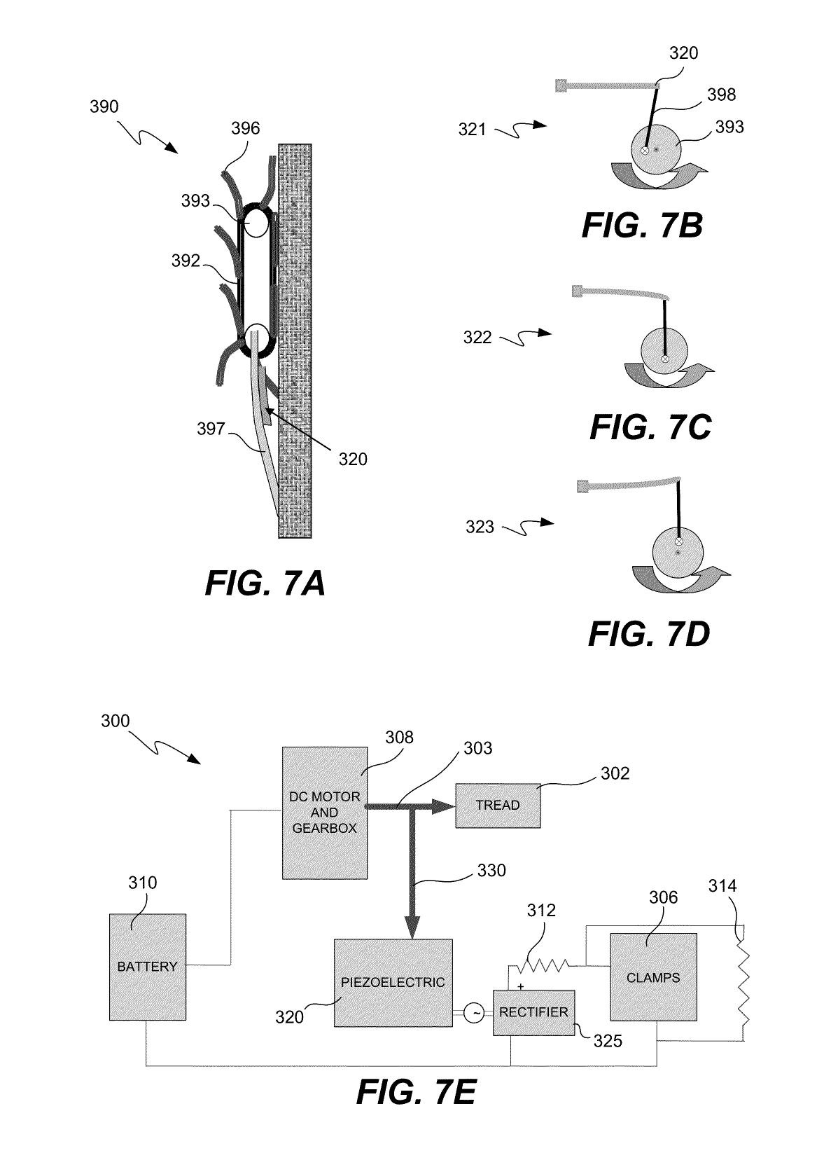

As another example, FIG. 7A illustrates in side elevation view an exemplary tracked wall-crawling robot modified with a piezoelectric generator according to another embodiment of the present invention. Robot 390 can be similar to robot 90 set forth above, in that it can include one or more tracks 392 situated around wheels 393 that are positioned to both sides of a main chassis. A plurality of electrostatic components 396 in the form of thin foils rotate with the tracks 392 to alternatively come in contact with and disengage from a wall surface or other foreign substrate. A tail 397 can extend off the back of the main chassis, with the end of the tail contacting the foreign substrate.

In addition, one or more piezoelectric elements 320 can be coupled to robot 390 at strategic locations. Such piezoelectric elements can be used to provide high voltage directly from experienced mechanical strains, as will be readily appreciated. As shown in FIG. 7A, piezoelectric element 320 can be coupled to tail 397 such that oscillatory bending strains or vibrations experienced by the tail while the overall robot 390 moves result in the driving of the piezoelectric element. In some embodiments, piezoelectric elements can be embedded within the tail with similar results. Alternatively or in addition to and combination with the foregoing, one or more piezoelectric elements can be driven in strain using a device motor.

FIGS. 7B-7D illustrate in side elevation views an exemplary piezoelectric element from the robot of FIG. 7A at first, second and third positions respectively. As shown, piezoelectric element 320 can be driven in oscillatory bending by a motor onboard the robot using a crank configuration. Alternatively, the element can be hand-cranked in lieu of using a motor. As shown at position 321, piezoelectric element 320 can be fixed at one end while the other end oscillates up and down depending upon the position of rotating shaft 398. Shaft 398 is cranked according to its off-centered coupling to wheel or roller 393. Piezoelectric element 320 is then mechanically strained as a result of its positional change through overall positions 321, then 322, and then 323 as wheel 393 continues to rotate.

As in the foregoing embodiments, one or more capacitors can be used to store electrical energy for discharge and use at a later time. In addition, one or more diodes can be used to can be used to rectify the piezo-induced current for storage or if the design produces an oscillatory voltage from the piezoelectric device. For example, a full wave rectifier may apply for such instances.

FIG. 7E illustrates in block diagram format an exemplary piezoelectric generator based power supply and voltage converter arrangement according to one embodiment of the present invention. Power arrangement 300 can be similar to power arrangements 100 and 200 disclosed above in that it includes a battery 310 that provides power to a DC driven motor 308. Motor 308 can similarly be adapted to drive a primary function of the overall device, such as wheels and/or treads 302. Again, electroadhesion can be conducted by one or more electrostatic clamps 306, which can include electrodes, insulators and the like, and optional currently limiting series or parallel discharge resistances 312, 314 can also be provided.

Unlike the foregoing arrangements, power arrangement 300 can include a piezoelectric generator 320 to facilitate ramping up the low voltage from the battery 310 to the high voltage needed for electrostatic applications. Again, the piezoelectric generator 320 can be driven as an output of the motor 308, with such a relationship being shown at 330. A full wave rectifier 325 may also be included as needed to rectify the oscillatory voltage output and thus facilitate the end use of piezoelectric generator 320. Again, while the primary function of the motor 308 can be considered as driving the tread 302, the secondary function 330 of driving the piezoelectric generator 320 in order to convert low voltage to high voltage enables the use of existing components (e.g., motor 308) to leverage a cheaper voltage convertor.

Although the various elements of FIGS. 7A-7E have been shown and described with respect to a particular piezoelectric application, it will be understood that a variety of other mechanical to electrical alternatives may also be suitable for the various applications provided herein. For example, one or more electroactive polymer (“EPAM”) elements can similarly be adapted to convert experienced mechanical strains into high voltages that are then used to drive the electrostatic applications of the device.

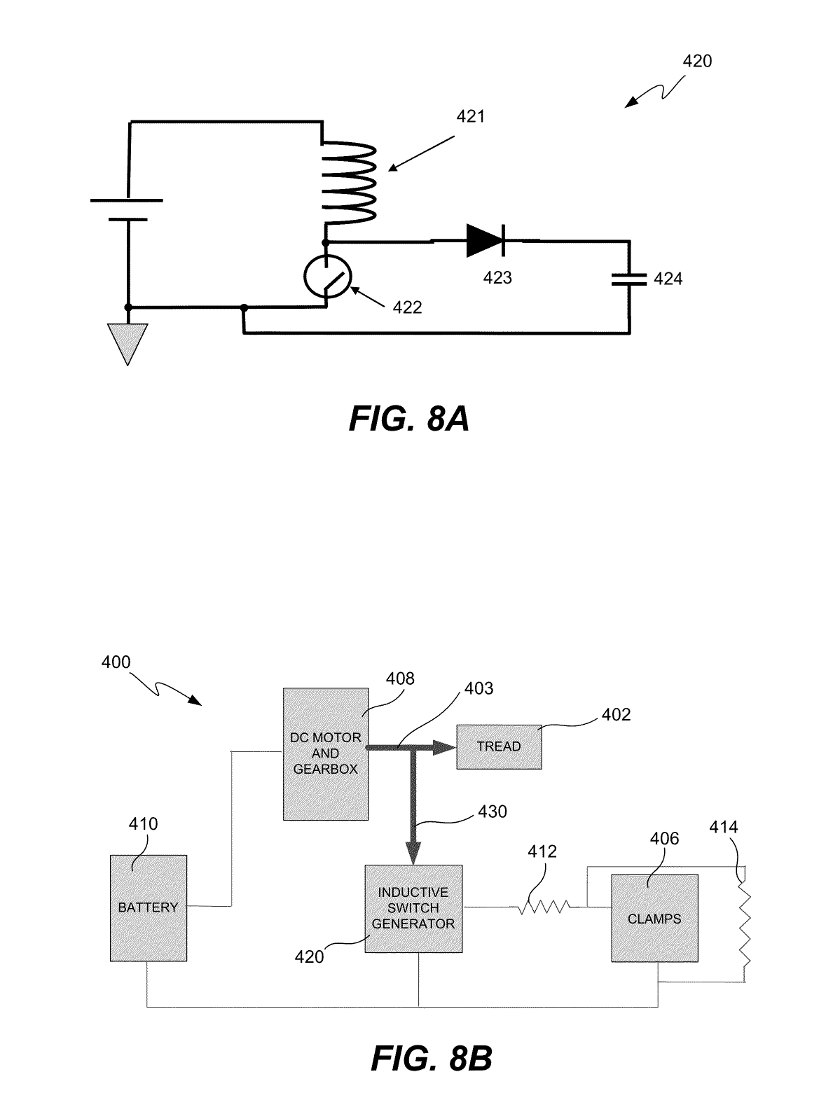

Continuing with FIG. 8A, a circuit diagram of an exemplary inductive switch generator arrangement is provided. Inductive switch generator circuit 420 can include an inductor 421 or other suitable magnetic component coupled in series with a switch 422 that is adapted to regulate the charge on the inductor, ultimately resulting in the step up of a low voltage input to a high voltage output of the circuit. One or more optional diodes 423 and storage capacitors 424 may also be used to store charge for later use, as will be appreciated. Circuit components may be duplicated, and other details may be included as desired.

Since many electroadhesive applications can work with unregulated power supplies, relatively simple inductor interrupting circuits, such as circuit 420, can be used to generate the needed high voltages. Such simple inductor circuits can involve interrupting a low voltage into the inductor so as to output a pulse at a higher and more usable voltage. Such higher voltages can then be used to directly power an electroadhesive device and/or charge a capacitor for later use. Many applications of electroadhesion can be made to work with a pulsed rather than a constant high voltage supply. As shown, the interrupt to the inductor 421 can be facilitated by way of switch 422, which can be controlled in a number of different ways.

In some embodiments, switch 422 can be electronically timed using a transistor or other form of timing circuitry. In some embodiments, switch 422 can be opened and closed in a purely mechanical fashion, such as by a motor. Such a motor driven toggling of the switch can be facilitated directly from the motor output, or can be provided as an indirect result of the motor output. As an example of an indirect result, the motor might provide an output that drives one or more wheels of a robot for overall robot locomotion. Another roller or device on the robot can be adapted to take advantage of and be driven separately by the robot motion, with such other roller or device being directly coupled to the switch.

Next, FIG. 8B illustrates in block diagram format an exemplary inductive switch generator based power supply and voltage converter arrangement. Power arrangement 400 can similarly include a battery 410 that provides power to a DC driven motor 408, which in turn drives a primary function of the overall device, such as wheels and/or treads 402. Again, electroadhesion can be conducted by one or more electrostatic clamps 406, which can include electrodes, insulators and the like, and optional currently limiting series or parallel discharge resistances 412, 414.

Power arrangement 400 can also include an inductive switch generator 420 such as the circuit of FIG. 8A to facilitate ramping up the low voltage from the battery 410 to the high voltage needed for electrostatic applications. Similar to the forgoing embodiments, the inductive switch generator 420 can be driven as an output of the motor 408, with such a relationship being shown at 430. Again, while the primary function of the motor 408 can be considered as driving the tread 402, the secondary function 430 of driving the inductive switch generator 420 in order to convert low voltage to high voltage enables the use of existing components (e.g., motor 408) to leverage a cheaper voltage convertor.

Various details of power arrangement 400 and inductive switch generator 420 can vary as may be desired for a particular application. Such details can include the switching component being a transistor, and/or the switching component having a resistance of less than about 5 ohms when in a “closed” state and a significantly higher resistance when in an “open” state. Other details can include the magnetic component actually being an inductor, the voltage gain of the circuit being at least double and up to about 100 times or more, and/or the circuit defining a structure having a volume of less than about 2000 mm³ and a weight of less than about 4 g. The switch can be toggled at a switching frequency of about 30 kHz or less in many embodiments, and at about 1 kHz or less in some instances. The capacitive device can be any of a wide variety of capacitors, and can even comprise an electroactive polymer in some embodiments. Alternative and/or other details may also apply, as may be desired for a particular application.

For any of the foregoing embodiments, it will be appreciated that the actual relative location(s) of the various high voltage conversion elements can vary as may be desired or suitable for a particular application. In fact, it is contemplated that each embodiment will function adequately with such elements being located in any of a variety of locations. One particular example, provided for purposes of illustration, can involve the location of such high voltage conversion elements within or about one or more rollers or wheels that drive a belt, track or tread for an overall device. Some examples of such components are provided with respect to FIGS. 4A-4D and 7A above, although other variations are also possible. In such instances where the high voltage electronics or other conversion elements are located within a belt roller or other similar component, the respective belt or track can then be adapted to pick up voltage automatically as it wraps around and rides such a roller.

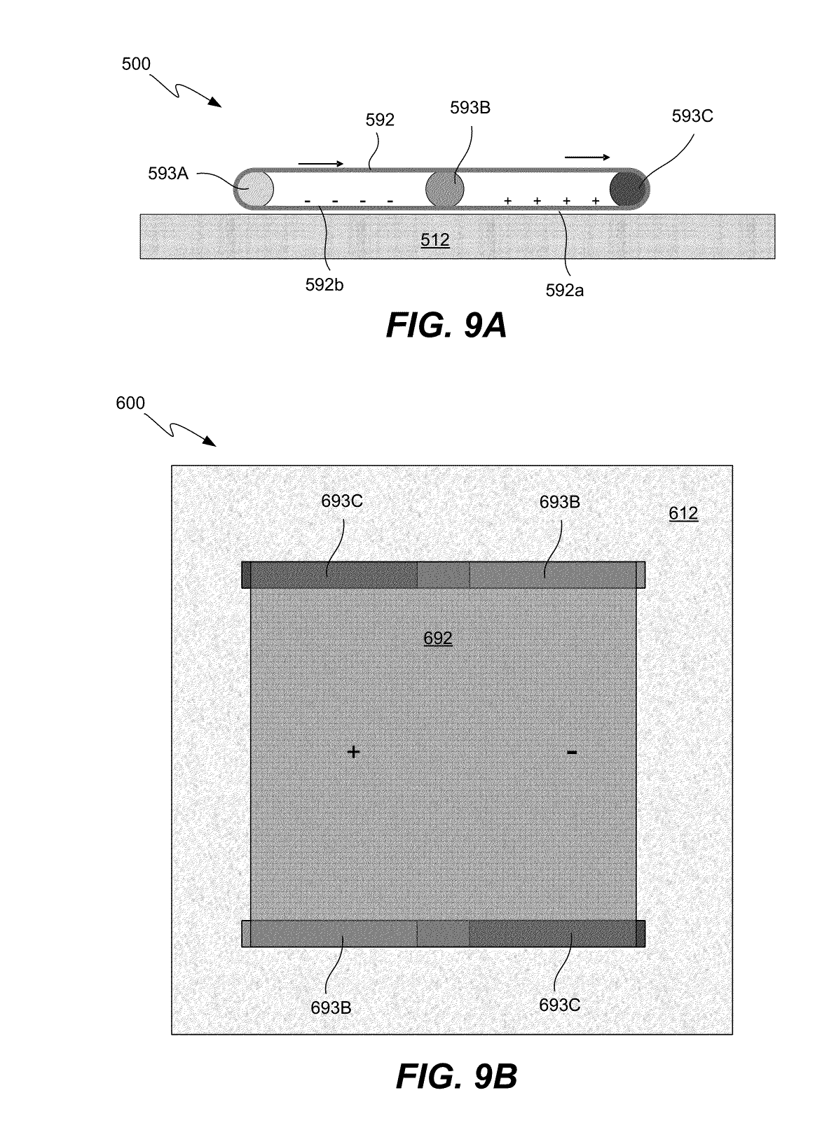

Other embodiments involving the use of existing components having a primary function also to facilitate a secondary function of moving electrical charges are also contemplated. Transitioning now to FIG. 9A, an exemplary belt and roller arrangement of an electroadhesive device with respect to a foreign substrate is illustrated in side elevation view. Electroadhesive device 500 can include a tread or belt 592 that is driven by a plurality of rollers 593A, 593B, 593C. As tread or belt 592 comes into contact with foreign substrate 512, electroadhesion is used to adhere the device 500 to the substrate by way of charges in the belt. Such charges can be provided initially by way of a separate voltage converter, which is not shown here for purposes of simplicity in illustration. In particular, portion 592a of belt 592 can carry a positive charge, while portion 592b of the belt carries a negative charge. The interaction of these two charges and foreign substrate 512 results in electroadhesion of the belt 592 and overall device 500 to the substrate.

Despite the constant rolling or motion of the belt, the charges at portions 592a and 592b are controlled by way of the rollers 593A, 593B, 593C. That is, each roller changes the charge on the belt as the belt travels past it, with such a change remaining until that portion of the belt passes the next roller. In this particular example, roller 593A can be a neutral roller that neutralizes the charge on the belt as the belt travels past it. Roller 593B can be a positively charged roller that results in a negative charge on the belt as the belt travels past it. Roller 593C can be a negatively charged roller that results in a positive charge on the belt as the belt travels past it. Of course, the exact arrangement of positive, negative and neutral rollers can be adjusted, and additional rollers such as multiples of each type may be added.

In effect, one or more rollers 593A, 593B, 593C are used to deposit and/or remove charges, rather than conducting charges using one or more electrodes in a conventional manner. As shown, the end result is that a voltage difference between the different belt portions 592a, 592b results in electroadhesion between the belt and the substrate. In addition to a simple belt, one or more other devices or features can also be used to enhance the effects of the electroadhesion. For example, various flaps, foils, hairs, cilia and the like may be used on the belt to facilitate compliance to the substrate. In addition, the belt 592 can comprise a track or tread that drives the overall device. Again, such an approach can serve to reduce complexity, cost and the number of overall parts for an electrostatic robot or device.

FIG. 9B illustrates in top plan view an alternative belt and roller arrangement of an electroadhesive device with respect to a foreign substrate. Electroadhesive device 600 can be similar to device 500, except that only two rollers are used rather than three. Tread or belt 692 is driven by four rollers 693B, 693C such that robot or device 600 is electrostatically adhered to foreign substrate 612. Rollers 693B can be positively charged, while rollers 693C can be negatively charged. The result to belt 692 is again to make one portion of the belt contacting the substrate negatively charged while the other portion contacting the substrate is positively charged. Since there is no neutral roller to remove charge, such charged portions simply remain until they come into contact with the next roller. Charged portions are located against the substrate as well as away from the substrate on the return path, as will be readily appreciated.

Where a brush motor is used, the brushes breaking and making contact with the motor windings can provide voltage spikes to the electroadhesion. As such, a diode can be used to prevent backflow in such arrangements. Where an oscillating voltage is available (such as from voltage spikes noted above), the voltage can be amplified using a capacitive voltage multiplier connected to the electroadhesion. The capacitors for the capacitive voltage multiplier can be patterned as part of the electroadhesion pad, and diodes can be added to facilitate this arrangement.

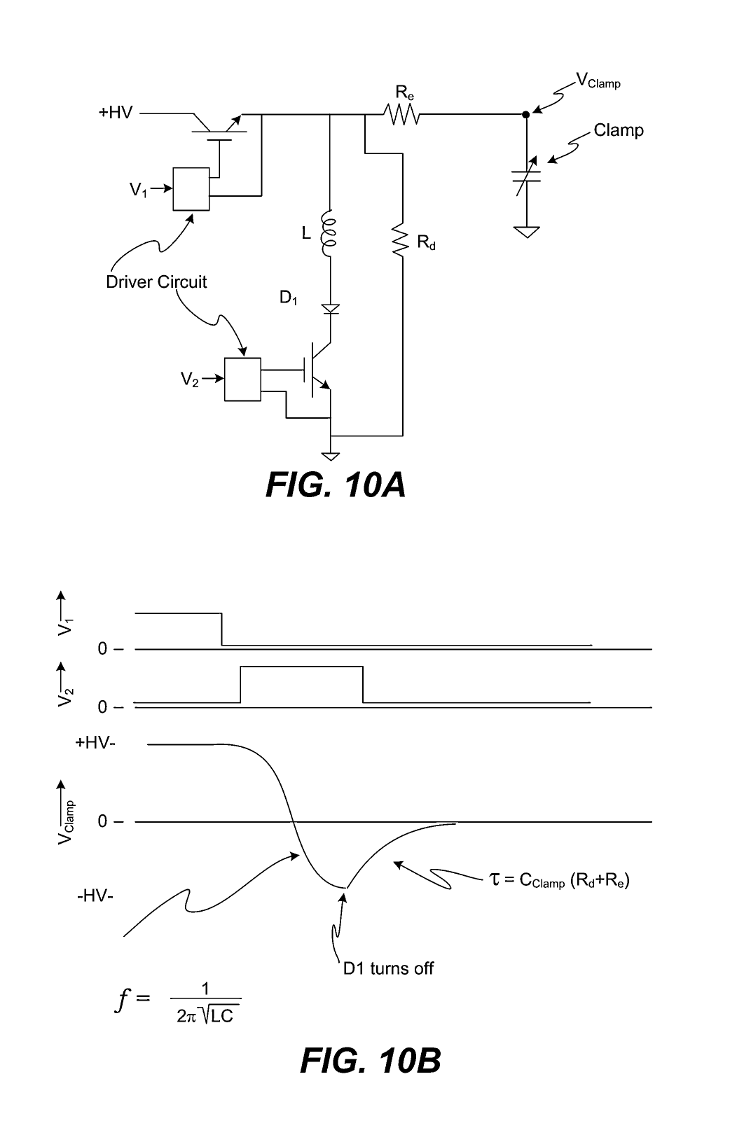

Given the various foregoing embodiments, it will be readily appreciated that many applications can provide electrostatic clamps sufficient to adhere items together electrostatically in a rapid apply and release fashion. As such, rapid yet reliable releases of electrostatically clamped or adhered items can be desirable in many instances. While simply lowering or shutting off power may suffice in some cases, even faster releases can be realized where the polarity of the charge is reversed in a safe yet reliable manner Moving next to FIG. 10A, a circuit diagram of an exemplary polarity reversal tank circuit for use in releasing an electrostatic clamp is provided, while FIG. 10B provides a graph of an exemplary voltage output for the polarity reversal tank circuit of FIG. 10A.

As shown, the circuit of FIG. 10A can be provided for generating a single negative release pulse. The resistor Rd prevents leaving a negative voltage on the electroadhesive clamp, while the resistor Re can be the electrode resistance or a separate resistor added for any additional reason, such as to limit the maximum current in a transistor. With respect to FIG. 10B, the pull-up transistor is first turned off by setting the input voltage to its driver circuit, V1, to zero. A certain delay elapses before the pull-down transistor is turned on by increasing V2 from zero to a high voltage (i.e., a logical “one”). This delay can be related to the time required to turn off the pull-up transistor.

When the pull-down transistor is on, the inductor and the clamp capacitance are effectively connected in parallel. This parallel circuit is an example of the well-known “LC tank” circuit, which will exhibit a damped sine wave oscillation if it is not driven externally. The oscillation frequency is related to L and the clamp capacitance by the equation provided in FIG. 10B. At the negative peak of the oscillation, diode D1 will turn off. Following this event, the clamp voltage will decay with an exponential waveform, with the time constant for this decay also being provided by equation in FIG. 10B.

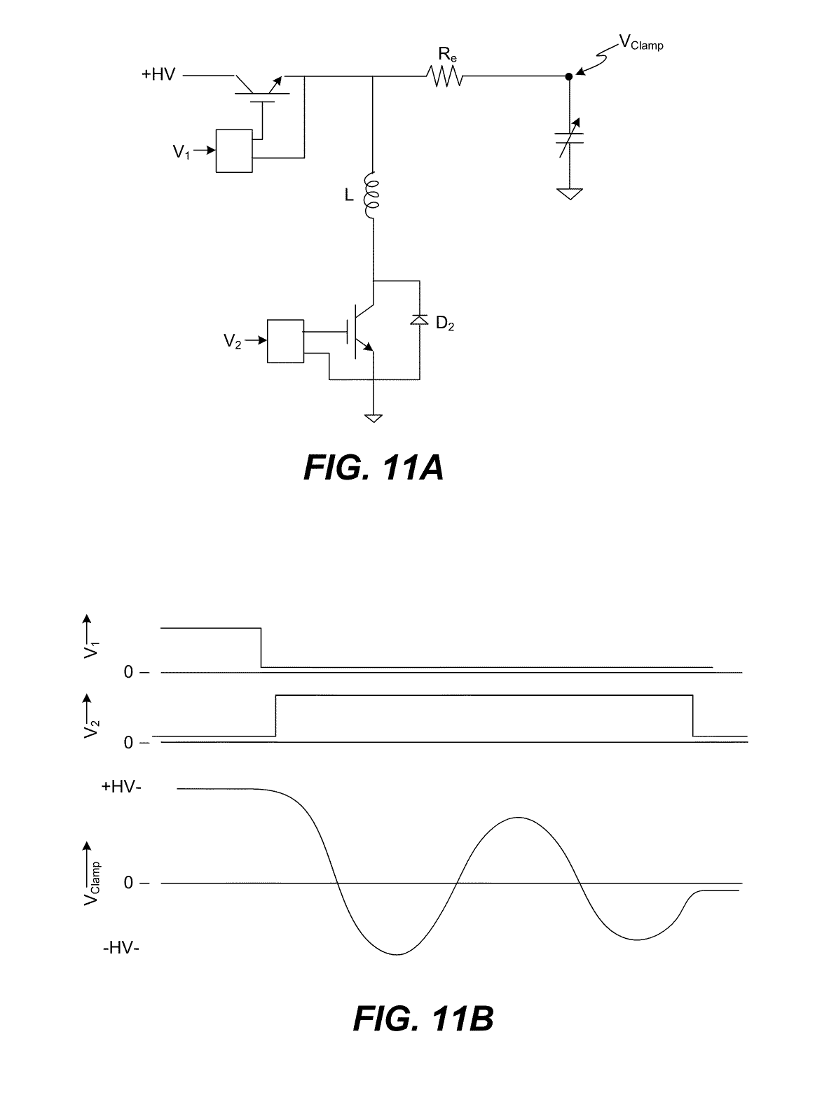

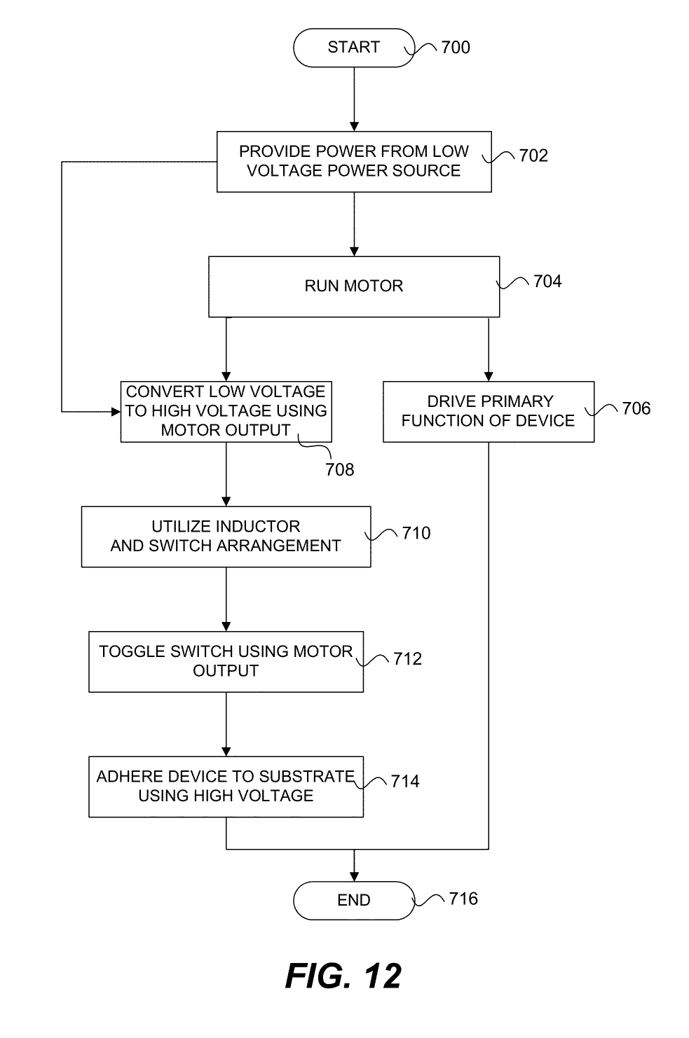

FIG. 11A illustrates a circuit diagram of an exemplary alternative polarity reversal tank circuit having a damped sine wave, while FIG. 11B provides a graph of an exemplary voltage output for the alternative polarity reversal tank circuit having a damped sine wave of FIG. 11A. As shown, the circuitry of FIG. 11A may be used to apply a damped sine wave to the clamp. Using this circuitry, any desired number of cycles of the sine wave may be obtained. As in the circuit of FIG. 10A, there will be a delay between the fall of V1 and the rise of V2. In the circuit of FIG. 11A, however, V2 remains high for a time related to the number of cycles desired. Also, the circuitry includes the diode D2, which conducts during the times between the negative and succeeding positive peaks of the clamp voltage.

Alternatively, or in addition to, these exemplary circuitry arrangements, other types of mechanical devices or techniques can also be used to facilitate a more rapid release of electrostatic forces in the various systems provided herein. Such other devices can include, for example, solenoids, electromagnets, vibrating motors and the like. Of course, other types or details in such circuits may also be used as desired, and it will be appreciated that the foregoing tank circuits, or any of a variety of suitable alternatives, can generally be used to facilitate the more rapid release or disengagement of electrostatically adhered or otherwise clamped items.

Such electrostatically clamped items can be any of the various robot or other object to foreign substrate embodiments provided above, for example. Such systems that may involve the rotation of a track having scales or other electrostatic clamping components can benefit from the ability to apply and disengage electrostatic forces rapidly. As noted above though, it is also contemplated that many other types of electrostatic applications may also generally be implicated, such as two components of the same device that may be electrostatically adhered to each other in an electrolaminate or other type of arrangement. For example, the waveform described in FIG. 11B can be used to ensure a more rapid release of electrolaminate scales in the same device relative to each other, so as to return to a lower stiffness state for the scales.

### Methods

Although a wide variety of applications involving providing high voltage for an electrostatic application from a low voltage power source can be imagined, one basic method is provided here as an example. Turning lastly to FIG. 14, a flowchart of an exemplary method of operating an electroadhesive device according to one embodiment of the present invention is provided. It will be readily appreciated that not every method step set forth in this flowchart is always necessary, and that further steps not set forth herein may also be included. For example, the provision of a motor is not necessary in all embodiments. Furthermore, the exact order of steps may be altered as desired for various applications.

Beginning with a start step 600, power is provided from a low voltage power source at process step 602. Again, such a low voltage power source can be, for example, one or more common or commercially available batteries. Again, one particular non-limiting example for the power source can involve the use of four serially arranged 1.5 volt “AA” sized batteries, although other suitable power sources are also possible. At process step 604, a motor is run using the low voltage power from the power source. Process steps 606 and 608 can then be performed in parallel as a result of the motor being run at step 604. Step 606 involves the motor driving a primary function of the overall electroadhesive device, while step 608 involves the motor output providing a basis for converting the low voltage of the power source to a high voltage. Since some power from the power source is provided for this purpose, this is reflected by a separate process flow directly from step 602 to step 608.

Converting voltage can be done in a number of ways, such as by using an inductor and switch arrangement, as set forth in process step 610. Under such an arrangement, the switch can be toggled using an output of the motor, as set forth in process step 612. With high voltage being provided as a result of steps 602 through 612, the overall device can be electrostatically adhered to a substrate using the high voltage at subsequent process step 614.

The method then finishes at and end step 616. Further steps not depicted can include, for example, the primary function of the device involving movement of the device or other locomotion. Other steps can include utilizing an electronic timer or a mechanical device between the motor output and the switch to regulate the switch toggling, for example, and any or all of the steps may be repeated any number of times, as may be desired.

Although the foregoing invention has been described in detail by way of illustration and example for purposes of clarity and understanding, it will be recognized that the above described invention may be embodied in numerous other specific variations and embodiments without departing from the spirit or essential characteristics of the invention. Various changes and modifications may be practiced, and it is understood that the invention is not to be limited by the foregoing details, but rather is to be defined by the scope of the claims.

What is claimed is:

1. An electroadhesive device, comprising:
a low voltage power source;
a motor adapted to receive power from the low voltage power source and provide an output that drives a primary function of the electroadhesive device;
a voltage convertor adapted to receive power from the low voltage power source and convert the low voltage to a high voltage using the output of the motor, wherein said voltage convertor is separate from said primary function of the electroadhesive device; and
one or more electrodes configured to apply the high voltage from said voltage convertor as an electrostatic adhesion voltage that produces an electrostatic force between the electroadhesive device and a foreign substrate, wherein said electrostatic force is suitable to maintain a current position of the electroadhesive device relative to the foreign substrate.

2. The electroadhesive device of claim 1, wherein said primary function of the electroadhesive device comprises a mechanism for locomotion.

3. The electroadhesive device of claim 2, wherein said mechanism for locomotion provides movement of the electroadhesive device.

4. The electroadhesive device of claim 3, wherein said electroadhesive device comprises a wall-crawling robot, and wherein said mechanism for locomotion comprises the movement of wheels or treads on the robot.

5. The electroadhesive device of claim 1, wherein said voltage convertor comprises a Van de Graff generator.

6. The electroadhesive device of claim 1, wherein said voltage convertor comprises a piezoelectric generator.

7. The electroadhesive device of claim 1, wherein said voltage convertor comprises an inductive switch generator.

8. The electroadhesive device of claim 7, wherein said inductive switch generator is adapted to provide pulses of high voltage.

9. The electroadhesive device of claim 7, wherein said inductive switch generator comprises a switch that is toggled by the output of the motor.

10. The electroadhesive device of claim 9, wherein said inductive switch generator further comprises a transistor adapted to help control the timing of the toggling of said switch.

11. The electroadhesive device of claim 1, wherein said low voltage power source comprises one or more commercially available batteries.

12. A power circuit adapted to increase the voltage of a low voltage power source for use in an electrostatic application, comprising:
a low voltage power source adapted to drive a separate motor; and
a voltage convertor adapted to receive power from the low voltage power source and convert the low voltage to a high voltage using an output of the separate motor, wherein driving said voltage convertor is not the primary function of the separate motor.

13. The power circuit of claim 12, further comprising:
one or more electrodes configured to apply the high voltage from said voltage convertor as an electrostatic adhesion voltage that produces an electrostatic force between an electroadhesive device including the power circuit and a foreign substrate, wherein said electrostatic force is suitable to maintain a current position of the electroadhesive device relative to the foreign substrate.

14. The power circuit of claim 12, wherein said voltage convertor includes a magnetic component and a switching component adapted to charge and discharge the magnetic component.

15. The power circuit of claim 14, wherein said magnetic component is an inductor and said switching component is a transistor.

16. The power circuit of claim 12, wherein said voltage convertor comprises a Van de Graff generator.

17. The power circuit of claim 12, wherein said voltage convertor comprises a piezoelectric generator.

18. A method of operating an electroadhesive device, comprising:
providing power from a low voltage power source at the electroadhesive device;
running a motor at the electroadhesive device using the power from the low voltage power source, wherein said running motor drives a primary function of the electroadhesive device;
converting the low voltage from the low voltage power source to a high voltage using the output of the motor, said converting being separate from the primary function of the electroadhesive device; and
adhering the electroadhesive device to a separate foreign substrate using one or more electrodes at the electroadhesive device, said one or more electrodes being configured to apply the high voltage as an electrostatic adhesion voltage that produces an electrostatic force between the electroadhesive device and the foreign substrate.

19. The method of claim 18, wherein said primary function of the electroadhesive device comprises a mechanism for locomotion.

20. The method of claim 18, wherein said converting comprises the use of an inductive switch generator, and further including the steps of:
utilizing an inductor and switch arrangement coupled to the low voltage power source; and
toggling the switch using the output of the motor.
